(19) United States
(12) Patent Application Publication
(10) Pub. No.: US 2018/0132116 A1
(43) Pub. Date: May 10, 2018

(54) SYSTEMS AND METHODS FOR MOTION ASSISTED COMMUNICATION

(71) Applicant: Invensense Inc., San Jose, CA (US)

(72) Inventors: Hemabh Shekhar, San Jose, CA (US); Ardalan Heshmati, San Jose, CA (US)

(21) Appl. No.: 15/795,177

(22) Filed: Oct. 26, 2017

Related U.S. Application Data
(60) Provisional application No. 62/413,306, filed on Oct. 26, 2016.

(51) Int. Cl. H04W 24/02; H04W 4/02; G01S 19/47; G01S 5/00; H01Q 3/38; H03G 3/30; H04W 76/10; G06F 15/18

(52) U.S. Cl. CPC H04W 24/02; H04W 4/02; G01S 19/47; G06F 15/18; H01Q 3/38; H03G 3/3042; H04W 76/10; G01S 5/0027

(57) ABSTRACT

Systems and devices are disclosed for communicating between a portable device and a first base station. A wireless communications link may be established between the portable device and the first base station. Sensor data indicative of motion of the portable device relative to the first base station may be obtained, such that communication parameters may be adjusted based at least in part on the motion sensor data.

### CROSS REFERENCE TO RELATED APPLICATIONS

This application claims priority from and benefit of U.S. Provisional Patent Application Ser. No. 62/413,306, filed Oct. 26, 2016, which is entitled “Motion-Assisted WiGig Communication,” which is assigned to the assignee hereof and is incorporated by reference in its entirety.

### FIELD OF THE PRESENT DISCLOSURE

This disclosure generally relates to motion sensors and more specifically to a portable device in communication with a base station, wherein communication parameters are adjusted based at least in part on information from the motion sensors.

### BACKGROUND

The development of microelectromechanical systems (MEMS) has enabled the incorporation of a wide variety of sensors into mobile devices, such as cell phones, laptops, tablets, gaming devices and other portable, electronic devices. Non-limiting examples of such sensors include an accelerometer, a gyroscope, a magnetometer, a pressure sensor, a microphone, a proximity sensor, an ambient light sensor, an infrared sensor, and the like. Further, sensor fusion processing may be performed to combine the data from a plurality of sensors to provide an improved characterization of the device's motion or orientation.

Head Mounted Displays (HMD) require a high refresh rate and a high resolution of the displayed images in order to obtain an optimal user experience. Unless the image content is generated by the HMD, the image content has to be transferred to the HMD by a second device, which will be referred to here as the HMD controller, or simply controller. The controller may be connected to the HMD by a cable, but a wireless connection is preferred to improve user freedom. Given the desire to provide the HMD with content at an appropriate resolution, the wireless connection requires a very high data rate, and a technology capable of achieving the required data rates is, for example, a wireless gigabit connection, which is also referred to as WiGig. Because of the high frequencies of the order of 60 GHz, the transmission suffers from high propagation loss. Therefore, most WiGig communications use beam forming and/or beam steering, and require a direct line of sight.

Head Mounted Displays are in most cases also equipped with inertial or motion sensors, such as accelerometers, gyroscopes, and/or magnetometers. These motion sensors are used to determine the motion and orientation of the HMD in space in order to generate to correct images in the Augmented Reality (AR) or Virtual Reality (VR). These motion sensors may be integrated in an Inertial Measurement Unit (IMU) or a Motion Processing Unit (MPU).

In light of the above, it would be desirable to provide techniques that use motion sensor information to enhance communication. To address these needs and others, this disclosure is directed to techniques for adjusting communication parameters based on motion sensor data as described in the materials below.

### SUMMARY

As will be described in detail below, this disclosure includes a method for wireless communication between a portable device and a first base station. The method may involve establishing a wireless communications link between the portable device and the first base station, obtaining sensor data indicative of motion of the portable device relative to the first base station and adjusting communication parameters based at least in part on the motion sensor data.

This disclosure also includes a portable device having a wireless communication module, a sensor assembly providing data indicative of motion of the portable device and a motion module configured to receive the sensor data to measure motion of the portable device, wherein the wireless communication module employs communication parameters adjusted based at least in part on the measured motion when communicating with a first base station.

This disclosure also includes a base station having a wireless communication module configured to receive information corresponding to motion of a portable device and to employ communication parameters adjusted based at least in part on the motion information when communicating with the portable device.

Still further, this disclosure includes a wireless communication system between a portable device and a base station. The portable device may have a wireless communication module, a sensor assembly providing data indicative of motion of the portable device and a motion module configured to receive the sensor data to measure motion of the portable device. The base station may also have a wireless communication module. The wireless communication modules may employ communication parameters adjusted based at least in part on the measured motion when communicating between the portable device and the base station.

### BRIEF DESCRIPTION OF THE DRAWINGS

FIG. 1 is a schematic diagram of portable device for providing sensor data according to an embodiment.

FIG. 2 is a schematic diagram of a head mounted display (HMD), a user controller and a system of base stations according to an embodiment.

FIG. 3 is a schematic representation of the wave front of a radio frequency signal having communication parameters that may be adjusted according to an embodiment.

FIG. 4 is a routine for providing wireless communication using motion sensor information according to an embodiment.

FIG. 5 is a schematic diagram an exchange of information for a complete beam optimization according to an embodiment.

FIG. 6 is a schematic diagram an exchange of information for a reduced beam optimization according to an embodiment.

FIG. 7 is a schematic diagram of determining change in user position based on wireless communication characteristics according to an embodiment.

### DETAILED DESCRIPTION

At the outset, it is to be understood that this disclosure is not limited to particularly exemplified materials, architectures, routines, methods or structures as such may vary. Thus, although a number of such options, similar or equivalent to those described herein, can be used in the practice or embodiments of this disclosure, the preferred materials and methods are described herein.

It is also to be understood that the terminology used herein is for the purpose of describing particular embodiments of this disclosure only and is not intended to be limiting.

The detailed description set forth below in connection with the appended drawings is intended as a description of exemplary embodiments of the present disclosure and is not intended to represent the only exemplary embodiments in which the present disclosure can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the specification. It will be apparent to those skilled in the art that the exemplary embodiments of the specification may be practiced without these specific details. In some instances, well known structures and devices are shown in block diagram form in order to avoid obscuring the novelty of the exemplary embodiments presented herein.

For purposes of convenience and clarity only, directional terms, such as top, bottom, left, right, up, down, over, above, below, beneath, rear, back, and front, may be used with respect to the accompanying drawings or chip embodiments. These and similar directional terms should not be construed to limit the scope of the disclosure in any manner.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present.

Some portions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving” or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments described herein may be discussed in the general context of processor-executable instructions residing on some form of non-transitory processor-readable medium, such as program modules, executed by one or more computers or other devices. Generally, program modules include routines, programs, objects, components, data structures, etc., that perform particular tasks or implement particular abstract data types. The functionality of the program modules may be combined or distributed as desired in various embodiments.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the exemplary wireless communications devices may include components other than those shown, including well-known components such as a processor, memory and the like.

The techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, performs one or more of the methods described above. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor. For example, a carrier wave may be employed to carry computer-readable electronic data such as those used in transmitting and receiving electronic mail or in accessing a network such as the Internet or a local area network (LAN). Of course, many modifications may be made to this configuration without departing from the scope or spirit of the claimed subject matter.

The various illustrative logical blocks, modules, circuits and instructions described in connection with the embodiments disclosed herein may be executed by one or more processors, such as one or more sensor processing units (SPUs), digital signal processors (DSPs), general purpose microprocessors, application specific integrated circuits (ASICs), application specific instruction set processors (ASIPs), field programmable gate arrays (FPGAs), or other equivalent integrated or discrete logic circuitry. The term “processor,” as used herein may refer to any of the foregoing structure or any other structure suitable for implementation of the techniques described herein. In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any conventional processor, controller, microcontroller, or state machine. A processor may also be implemented as a combination of computing devices, e.g., a combination of a Motion Processor Unit (MPU) or Sensor Processing Unit (SPU) and a microprocessor, a plurality of microprocessors, one or more microprocessors in conjunction with an MPU/SPU core, or any other such configuration.

Unless defined otherwise, all technical and scientific terms used herein have the same meaning as commonly understood by one having ordinary skill in the art to which the disclosure pertains.

Finally, as used in this specification and the appended claims, the singular forms “a, “an” and “the” include plural referents unless the content clearly dictates otherwise.

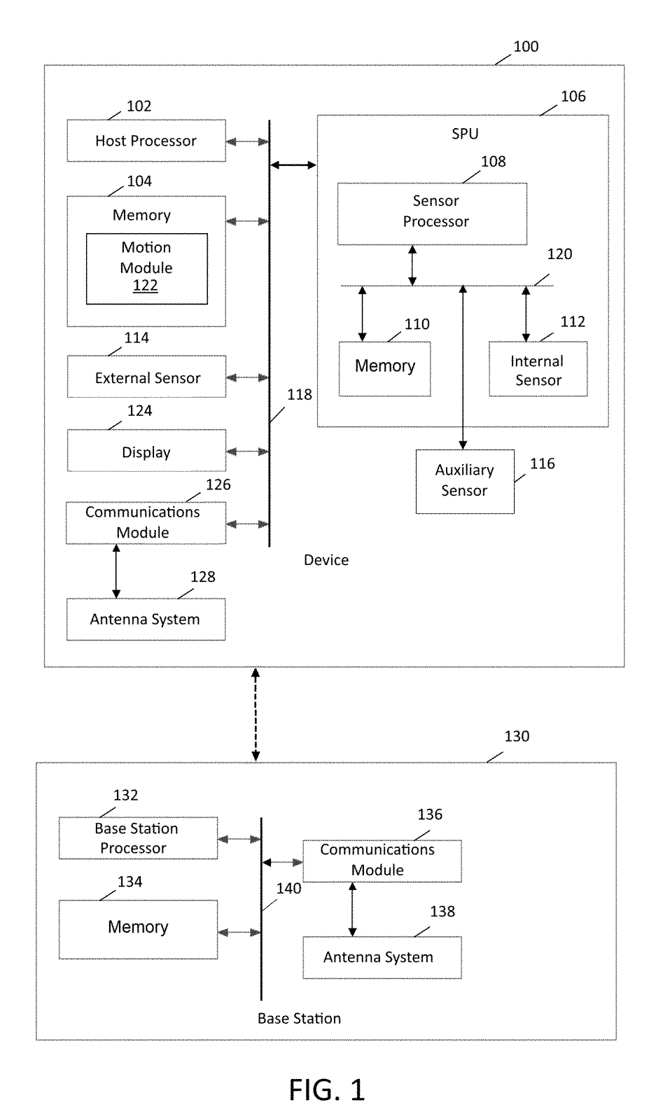

Details regarding one embodiment of portable device 100 including features of this disclosure are depicted as high level schematic blocks in FIG. 1. As will be appreciated, device 100 may be implemented as a portable device or apparatus, such as a head mounted display (HMD), that can be moved in space by a user and its motion and/or orientation in space therefore sensed. The orientation measurement may be part of a sequence of orientations, for example, corresponding to the user tracking a virtual object or feature displayed by the HMD. For example, such a portable device may be a dedicated HMD or other AR/VR device, or may be another portable device having capabilities that may be leveraged to provide some degree of functionality associated with a HMD, including a mobile phone (e.g., cellular phone, a phone running on a local network, or any other telephone handset), wired telephone (e.g., a phone attached by a wire), personal digital assistant (PDA), video game player, video game controller, navigation device, activity or fitness tracker device (e.g., bracelet or clip), smart watch, other wearable device, mobile internet device (MID), personal navigation device (PND), digital still camera, digital video camera, binoculars, telephoto lens, portable music, video, or media player, remote control, or other handheld device, or a combination of one or more of these devices. More generally, the portable device 100 may be any device in communication with a base station that would benefit from determining its orientation or motion relative to the base station, for example, for the purpose of line-of sight communication.

As shown, device 100 includes a host processor 102, which may be one or more microprocessors, central processing units (CPUs), or other processors to run software programs, which may be stored in memory 104, associated with the functions of device 100. In some embodiments, information concerning the relative orientation/position of portable device 100 with respect to a base station may be stored to track characteristics of antennas being used to communicate, such as by storing a geometric model of any involved antennas or antenna arrays, and may be used for any desired purpose, including determining which antennas are in line of sight. Multiple layers of software can be provided in memory 104, which may be any combination of computer readable medium such as electronic memory or other storage medium such as hard disk, optical disk, etc., for use with the host processor 102. For example, an operating system layer can be provided for device 100 to control and manage system resources in real time, enable functions of application software and other layers, and interface application programs with other software and functions of device 100. Similarly, different software application programs such as menu navigation software, games, camera function control, navigation software, communications software, such as telephony or wireless local area network (WLAN) software, or any of a wide variety of other software and functional interfaces can be provided. In some embodiments, multiple different applications can be provided on a single device 100, and in some of those embodiments, multiple applications can run simultaneously.

Device 100 includes at least one sensor assembly, as shown here in the form of integrated sensor processing unit (SPU) 106 featuring sensor processor 108, memory 110 and internal sensor 112. Memory 110 may store algorithms, routines or other instructions for processing data output by internal sensor 112 and/or other sensors as described below using logic or controllers of sensor processor 108, as well as storing raw data and/or motion data output by internal sensor 112 or other sensors. Memory 110 may also be used for any of the functions associated with memory 104. Internal sensor 112 may be one or more sensors for measuring motion of device 100 in space, such as an accelerometer, a gyroscope, a magnetometer, a pressure sensor or others. Depending on the configuration, SPU 106 measures one or more axes of rotation and/or one or more axes of acceleration of the device. In one embodiment, internal sensor 112 may include rotational motion sensors or linear motion sensors. For example, the rotational motion sensors may be gyroscopes to measure angular velocity along one or more orthogonal axes and the linear motion sensors may be accelerometers to measure linear acceleration along one or more orthogonal axes. In one aspect, three gyroscopes and three accelerometers may be employed, such that a sensor fusion operation performed by sensor processor 108, or other processing resources of device 100, combines data from internal sensor 112 to provide a six axis determination of motion or six degrees of freedom (6DOF). As desired, internal sensor 112 may be implemented using Micro Electro Mechanical System (MEMS) to be integrated with SPU 106 in a single package. Exemplary details regarding suitable configurations of host processor 102 and SPU 106 may be found in, commonly owned U.S. Pat. No. 8,250,921, issued Aug. 28, 2012, and U.S. Pat. No. 8,952,832, issued Feb. 10, 2015, which are hereby incorporated by reference in their entirety. Suitable implementations for SPU 106 in device 100 are available from InvenSense, Inc. of Sunnyvale, Calif.

Alternatively or in addition, device 100 may implement a sensor assembly in the form of external sensor 114. This is optional and not required in all embodiments. External sensor may represent one or more sensors as described above, such as an accelerometer and/or a gyroscope. As used herein, “external” means a sensor that is not integrated with SPU 106 and may be remote or local to device 100. Also alternatively or in addition, SPU 106 may receive data from an auxiliary sensor 116 configured to measure one or more aspects about the environment surrounding device 100. This is optional and not required in all embodiments. For example, a pressure sensor and/or a magnetometer may be used to refine motion determinations made using internal sensor 112. In one embodiment, auxiliary sensor 116 may include a magnetometer measuring along three orthogonal axes and output data to be fused with the gyroscope and accelerometer inertial sensor data to provide a nine axis determination of motion. In another embodiment, auxiliary sensor 116 may also include a pressure sensor to provide an altitude determination that may be fused with the other sensor data to provide a ten axis determination of motion. Although described in the context of one or more sensors being MEMS based, the techniques of this disclosure may be applied to any sensor design or implementation.

In the embodiment shown, host processor 102, memory 104, SPU 106 and other components of device 100 may be coupled through bus 118, while sensor processor 108, memory 110, internal sensor 112 and/or auxiliary sensor 116 may be coupled though bus 120, either of which may be any suitable bus or interface, such as a peripheral component interconnect express (PCIe) bus, a universal serial bus (USB), a universal asynchronous receiver/transmitter (UART) serial bus, a suitable advanced microcontroller bus architecture (AMBA) interface, an Inter-Integrated Circuit (I2C) bus, a serial digital input output (SDIO) bus, a serial peripheral interface (SPI) or other equivalent. Depending on the architecture, different bus configurations may be employed as desired. For example, additional buses may be used to couple the various components of device 100, such as by using a dedicated bus between host processor 102 and memory 104.

Algorithms, routines or other instructions for processing sensor data may be employed by motion module 120 to perform any of the operations associated with the techniques of this disclosure, such as determining the motion, location, distance and/or orientation of portable device 100 in relation to one or more communicating base stations. Determining the motion or orientation of portable device 100 may involve sensor fusion or similar operations performed by SPU processor 108. In other embodiments, some, or all, of the processing and calculation may be performed by the host processor 102, which may be using the host memory 104, or any combination of other processing resources. One or more additional internal sensors, such as internal sensor 112 may be integrated into SPU 102 as desired. If provided, external sensor 114, internal sensor 112, and/or auxiliary sensor 116 may include one or more sensors, such as accelerometers, gyroscopes, magnetometers, pressure sensors, microphones, proximity, and ambient light sensors, and temperature sensors among others sensors. As used herein, an internal sensor refers to a sensor implemented using the MEMS techniques for integration with SPU 106 into a single chip. Similarly, an external sensor as used herein refers to a sensor carried on-board device 100 that is not integrated into SPU 106. An accelerometer, gyroscope and/or any other sensor used in the techniques of this disclosure may be implemented as an internal or external sensor as desired.

Portable device 100 may also include display 124, which in an embodiment implemented as a HMD may be configured to deliver content that includes stereoscope information to simulate a three dimensional virtual environment. In this schematic representation, display 124 may also be considered as delivering audio information, such as through a suitable speaker system. To obtain the information associated with virtual reality and augmented reality applications or other similar uses of a HMD device, portable device 100 may be in communication with a base station having increased computational resources to generate and serve the content delivered to the user by portable device 100, such as through communication module 126 that may employ antenna system 128, which may be an array. In some embodiments, communications module 126 may employ a Wireless Local Area Network (WLAN) conforming to Institute for Electrical and Electronic Engineers (IEEE) 802.11 protocols, featuring multiple transmit and receive chains to provide increased bandwidth and achieve greater throughput. For example, the 802.11ad (WiGIG™) standard includes the capability for devices to communicate in the 60 GHz frequency band over four, 2.16 GHz-wide channels, delivering data rates of up to 7 Gbps. Other standards may also involve the use of multiple channels operating in other frequency bands, such as the 5 GHz band, or other systems including cellular-based and WLAN technologies such as Universal Terrestrial Radio Access (UTRA), Code Division Multiple Access (CDMA) networks, Global System for Mobile Communications (GSM), IEEE 802.16 (WiMAX), Long Term Evolution (LTE), other transmission control protocol, internet protocol (TCP/IP) packet-based communications, or the like may be used. In some embodiments, multiple communication systems may be employed to leverage different capabilities. Typically, communications involving higher bandwidths may be associated with greater power consumption, such that other channels may utilize a lower power communication protocol such as BLUETOOTH®, ZigBee®, ANT or the like. Further, while wireless communication allow for greater freedom of movement, a wired connection may be used for the communication of some information between various components of the system depending on the embodiment. Device 100 may have one or more user (hand) controllers associated with the device, which may communicate with device 100 or the base station also through one or more of the methods mentioned here.

As will be described in further detail below, portable device 100 may be in communication with a base station 130 as desired. Generally, base station 130 may include host processor 132 and memory 134 to implement any desired operations, including the delivery of content to portable device 100. As such, base station 130 may also include communication module 136, which may communicate using antenna system 138, which may also be an array, using one or more protocols such as those noted above. As desired, motion module 120 may be configured to determine aspects associated with the motion of portable device 100 relative to base station 130, such as to estimate any characteristics affecting the transmission of signals between antenna system 128 of portable device 100 and antenna system 138 of base station 130. For example, the wireless communication protocol employed by communications modules 126 and 136 may rely on a line of sight relationship between one or more antennas of the respective arrays. Alternatively or in addition, the respective orientation and/or the location of one or more antennas of antenna systems 128 and 138 may be determined using motion module 120 and employed by communications modules 126 and 136 when exchanging information according to the techniques of this disclosure. Such determinations may be absolute or relative as warranted. Examples of determining the position changed based on motion sensors may be found in co-pending, commonly owned U.S. patent application Ser. No. 14/537,503, filed Nov. 10, 2014, which is hereby incorporated by reference in its entirety.

In addition, portable devices 100 and base station 130 may communicate either directly or indirectly, such as through one or multiple interconnected networks. As will be appreciated, a variety of systems, components, and network configurations, topologies and infrastructures, such as client/server, peer-to-peer, or hybrid architectures, may be employed to support distributed computing environments. For example, computing systems can be connected together by wired or wireless systems, by local networks or widely distributed networks. Currently, many networks are coupled to the Internet, which provides an infrastructure for widely distributed computing and encompasses many different networks, though any network infrastructure can be used for exemplary communications made incident to the techniques as described in various embodiments. Memory 134 may store information concerning the relative orientation/position of portable device 100 with respect to base station 130, such as a geometric model as discussed of any involved antennas as discussed above. Useful information may include characteristics related to how the antenna array is positioned/oriented with respect to the motion sensors, or more generally, any information that may be used to determine how motion effects line of sight communication. Such information may be with regard to either or both of base station 130 and portable device 100. For example, antennas mounted on rigid surface have a geometry that may be used to model angle-of-arrival and hence estimate beam steering weight for each antenna. Other techniques may include estimating a desired combining weight using wireless training signals. Any components of base station 130, including base station processor 132, memory 134, and communications module 136 may be coupled by bus 140 in the manner described for bus 118 and 120, or may employ any other suitable architecture.

As will be appreciated, host processor 102 and/or sensor processor 108 may be one or more microprocessors, central processing units (CPUs), or other processors which run software programs for device 100 or for other applications related to the functionality of device 100. For example, different software application programs such as menu navigation software, games, camera function control, navigation software, and phone or a wide variety of other software and functional interfaces can be provided. In some embodiments, multiple different applications can be provided on a single device 100, and in some of those embodiments, multiple applications can run simultaneously on the device 100. Multiple layers of software can be provided on a computer readable medium such as electronic memory or other storage medium such as hard disk, optical disk, flash drive, etc., for use with host processor 102 and sensor processor 108. For example, an operating system layer can be provided for device 100 to control and manage system resources in real time, enable functions of application software and other layers, and interface application programs with other software and functions of device 100. In some embodiments, one or more motion algorithm layers may provide motion algorithms for lower-level processing of raw sensor data provided from internal or external sensors. Further, a sensor device driver layer may provide a software interface to the hardware sensors of device 100. Some or all of these layers can be provided in host memory 104 for access by host processor 102, in memory 110 for access by sensor processor 108, or in any other suitable architecture.

In one aspect, implementing motion module 120 in SPU 106 may allow the operations described in this disclosure to be performed with reduced or no involvement of host processor 102. As will be appreciated, this may provide increased power efficiency and/or may free host processor 102 to perform any other task(s). However, the functionality described as being performed by motion module 120 may be implemented using host processor 102 and memory 104 as indicated in FIG. 1 or any other combination of hardware, firmware and software or other processing resources available in portable device 100.

In the described embodiments, a chip is defined to include at least one substrate typically formed from a semiconductor material. A single chip may be formed from multiple substrates, where the substrates are mechanically bonded to preserve the functionality. A multiple chip includes at least two substrates, wherein the two substrates are electrically connected, but do not require mechanical bonding. A package provides electrical connection between the bond pads on the chip to a metal lead that can be soldered to a PCB. A package typically comprises a substrate and a cover. Integrated Circuit (IC) substrate may refer to a silicon substrate with electrical circuits, typically CMOS circuits. In some configurations, a substrate portion known as a MEMS cap provides mechanical support for the MEMS structure. The MEMS structural layer is attached to the MEMS cap. The MEMS cap is also referred to as handle substrate or handle wafer. In the described embodiments, an electronic device incorporating a sensor may employ a sensor tracking module also referred to as Sensor Processing Unit (SPU) that includes at least one sensor in addition to electronic circuits. The sensor, such as a gyroscope, a magnetometer, an accelerometer, a microphone, a pressure sensor, a proximity sensor, or an ambient light sensor, among others known in the art, are contemplated. Some embodiments include accelerometer, gyroscope, and magnetometer, which each provide a measurement along three axes that are orthogonal to each other. Such a device is often referred to as a 9-axis device. Other embodiments may not include all the sensors or may provide measurements along one or more axes. The sensors may be formed on a first substrate. Other embodiments may include solid-state sensors or any other type of sensors. The electronic circuits in the SPU receive measurement outputs from the one or more sensors. In some embodiments, the electronic circuits process the sensor data. The electronic circuits may be implemented on a second silicon substrate. In some embodiments, the first substrate may be vertically stacked, attached and electrically connected to the second substrate in a single semiconductor chip, while in other embodiments, the first substrate may be disposed laterally and electrically connected to the second substrate in a single semiconductor package.

In one embodiment, the first substrate is attached to the second substrate through wafer bonding, as described in commonly owned U.S. Pat. No. 7,104,129, which is incorporated herein by reference in its entirety, to simultaneously provide electrical connections and hermetically seal the MEMS devices. This fabrication technique advantageously enables technology that allows for the design and manufacture of high performance, multi-axis, inertial sensors in a very small and economical package. Integration at the wafer-level minimizes parasitic capacitances, allowing for improved signal-to-noise relative to a discrete solution. Such integration at the wafer-level also enables the incorporation of a rich feature set which minimizes the need for external amplification.

In the described embodiments, raw data refers to measurement outputs from the sensors which are not yet processed. Motion data may refer to processed and/or raw data. Processing may include applying a sensor fusion algorithm or applying any other algorithm. In the case of a sensor fusion algorithm, data from a plurality of sensors may be combined to provide, for example, an orientation of the device. In the described embodiments, a SPU may include processors, memory, control logic and sensors among structures.

A frame of reference for a portable device such as device 100 may be the body frame, having three orthogonal axes. Switching from the body frame to the world frame or any other suitable reference frame (such as e.g. a reference frame associated with one or more of the base stations), or vice versa, may be performed by apply the appropriate rotation to the data. Similarly, the world frame may have axes fixed to the Earth, such as by aligning the Z axis of the world frame with the gravity vector resulting from Earth's gravity field, pointing from the surface of the Earth to the sky. Although the math and descriptions provided in this disclosure are in the context of these frames, one of skill in the art will realize that similar operations may be performed using other definitions and frames of reference. All the teachings could be redone with different definitions. Thus, the orientation of a portable device may be expressed as the rotational operation that translates the body frame to the world frame, such as a rotation operation that aligns the Z axis of the body frame with the gravity vector. In some embodiments, the rotation operation may be expressed in the form of a unit quaternion. As used herein, the terms “quaternion” and “unit quaternion” may be used interchangeably for convenience. Accordingly, a quaternion may be a four element vector describing the transition from one rotational orientation to another rotational orientation and may be used to represent the orientation of a portable device. A unit quaternion has a scalar term and 3 imaginary terms. In this disclosure, the quaternion is expressed with the scalar term first followed by the imaginary terms but, appropriate modifications may be made to the formulas, equations and operations to accommodate different definitions of quaternion.

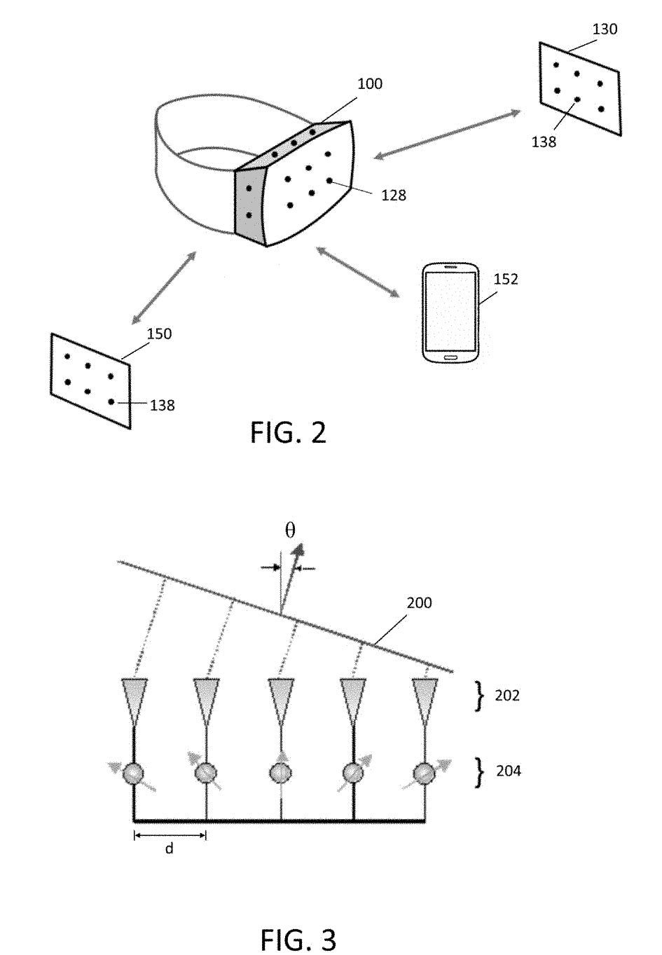

One exemplary system is depicted in FIG. 2, showing an architecture having a single HMD portable device 100 that communicates with base station 130. Depending on the embodiment, one or more additional base stations 150 may be utilized, such as to increase the number of antennas in the respective antenna systems having a line of sight condition or to otherwise provide an improved communication channel. For example, as indicated, one or more of antenna systems 128 and 138 may be configured as arrays. Base station 130 and 150 (and others) may be in communication with each other to allow for selection between the base stations based on the determined motion of portable device 128. In a further aspect, one or more user controllers 152 may be associated with portable device 100, such as to allow input of commands or the like. As will be appreciated, each controller 152 may be held in a hand of the user or may be secured to a location on the user's body and therefore provide feedback regarding the position or actions of the user.

User controller 152 may share some or all of the architecture indicated for portable device 100, particularly with regard to the sensor and processing systems. User controller 152 and portable device 100 may communicate using any suitable wired or wireless system, including those described above. As desired, user controller 152 may be implanted using a device having additional functionality, such as a smart phone or other portable device, or may be dedicated. Any portion of the computational resources may be distributed between portable device 100 and user controller 152. Further, user controller 152 may implement one or more antennas as part of antenna system 128 or may have its own communication module and antenna system, which in turn may be in communication with portable device 100. As will be appreciated, if user controller 152 has separate motion sensors, these may be used in addition to provide a more accurate determination of the user's motion with respect to base station 130. More generally, some or all of the functions described above regarding portable device 100 may be distributed among portable device 100 and user controller 152.

In FIG. 2, portable device 100 and base station 130 are depicted as having antenna system 128 and 138 implemented as antenna arrays for transmitting data and/or receiving data. Each dot represents an individual antenna element, but the amount and distribution of antenna merely serves as a non-limiting example, and many different variations may be used. For example, antenna system 128 of portable device 100 is shown as a planar antenna, but may also be of any three dimensional shape and form. The antenna systems may be rigid or may be deformable. Further, this illustration shows antennas on all sides of portable device 100, but the antennas may also be mounted on the headband used for wearing portable device 100 or on other related structures. In one version, antenna system 128 may be mounted only on the face of portable device 100, facing away from the user. As noted, the portable device 100 may be a dedicated device (e.g. Oculus Rift), but may also consist of a frame to which another device, such as e.g. a smartphone is mounted (e.g. Samsung Gear VR). Therefore, the antennas may be mounted on the dedicated device, or in the frame of the frame holding the external device, or in both. The antennas may then be controlled from the device or from a controller within the frame. In applications employing 802.11ad or other similar protocols, a line of sight channel may be required so that only the antennas that are in a line of sight condition need to be operated, and will have non-zero weights. Power savings may be achieved by disabling antenna elements not in a line of sight condition.

The communication modules 126 and 136 in portable device 100 and base station 130 respectively may be used to communicate content to be delivered, typically involving base stations 130 being the source of the content and delivering the content to portable device 100. Any characteristics regarding the position or orientation of portable device 100 with respect to base station 130 as determined by motion module 120 may be communicated. As discussed above, the information may be transmitted over the same channel used for the content, or may be delivered over a different channel having different attributes, such as lower power. At least two aspects are involved when determinations of motion module 122, including the formatting of information being delivered, such as by display 124, and the adjusting of one or more parameters associated with communication between portable device 100 and base station 130, including transmission and/or reception parameters. Although depicted as being implemented in portable device 100, some or all the functionality associated with motion module 122 may performed base station processor 132, executing instructions stored in memory 134. For example, sensor data and other relevant information measured at portable device 100 may be communicated to base station 130, for tailoring the content delivered and/or for optimizing communications. For example, portable device 100 may process the sensor data to determine any position/orientation change, which may then be sent to base station 130, or raw sensor measurement may be sent directly to base station 130 for motion determination.

As indicated in FIG. 3, radio frequency (RF) waves in wireless applications may be assumed to have a planar wave front 200, such that it reaches the antennas of a phased array at different delays. The antenna array of antenna system 128 or 138 is depicted with each antenna 202 driven by controller 204 to generate a scan angle or steering angle θ that depends on the phase imparted by controller 204 to each antenna 202 for a beam steering application. These principles may be applied whether the antenna system is used for transmitting and for receiving signals. To maximize the signal-to-noise ratio (SNR), input (for transmission) or output (for reception) the components of each antenna 202 should be added coherently. In this example, a Uniform Linear phased Array (ULA) transmitter is depicted with beam steering angle θ. The (complex) weight vector w for the phase correction or phase shift applied to the array of antennas with an antenna spacing d is given as Equation (1): θ

$$w = [ \begin{matrix}{e}^{j 2 π \frac{2 d}{λ} sin θ} & {e}^{j 2 π \frac{d}{λ} sin θ} & 1 & {e}^{- j 2 π \frac{d}{λ} sin θ} & {e}^{- j 2 π \frac{2 d}{λ} sin θ}\end{matrix} ] \qquad ( 1 )$$

The phased arrays need not be linear; the antennas could be arranged in any shape or form, which may be based on the required beam pattern. The antenna array may be one dimensional or two dimensional depending on the application and the degree of freedom required for the steering. In order to steer the beam in two directions, a two dimensional array may be required. The spatial relationship of antennas 202 in either antenna system 128 or antenna system 138 may be known from motion module 122, for example as represented in a geometrical model, so that the antenna position information may be used to calculate the required phase shift for each individual antenna 202 or group of antennas within the antenna array. The same principle of adapting the phase to compensate for any differences in time of arrival applies for any shape of the antenna arrays. The phase shifters could be analog or digital and can be at RF or baseband.

Similar to beam steering, beam forming is a technique to point the beam in desired direction and give the beam the correct shape. The weights may be estimated and applied in digital baseband to achieve to correct direction and shape of the beam. Examples of adaptive beamforming techniques employed in 802.11ad protocols include equal gain combining (EGC) and maximum ratio combining (MRC). These techniques can also be applied to either transmit or receive. The goal and operating principal of these techniques is same as beam steering, i.e. maximizing SNR, however the combining weights may be estimated based on the wireless channel between transmitter and receiver. The wireless channel, h, may be estimated using a training sequence.

Assuming there are N antennas in antenna system 128 of portable device 100, and one or more antennas used by base station 130 for delivering audio and visual content, the transmission channel should be estimated and optimized for all the N antennas. Typically, the number of antennas is large and it requires significant computation to estimate the complex weights each antenna 202. As noted above, providing multiple antennas in different positions may be desirable to increase the number of antennas that will be in a line of sight condition. A technique employing EGC may be implemented using Equation (2), in which arg are the angles of the complex channel estimates:

w=e^{-j arg h} (2)

Alternatively, a technique employing MRC may be implemented using Equation (3), in which h* is complex conjugate of the channel estimate:

w=h* (3)

In its general form, the complex weight wᵢ for antenna i in the array can be given by Equation (4) using the signal amplitude aᵢ and the phase φᵢ:

wᵢ=aᵢe^{jφ}^{ᵢ} (4)

As discussed above, the beam steering and/or beam forming in arrays 128 and/or 138 may be performed by adapting amplitude aᵢ and the phase φᵢ to obtain the desired result. Although the examples shown here are in the context of a single portable device 100 and a single base station 130, the same principles may be applied when there are multiple portable devices 100 and/or multiple base stations 130 and 150. For example, a single antenna array can be used to generate multiple beams by adjusting the amplitudes and phases accordingly. Different sections of the array may be used for different beams, or the same sections (i.e. antennas) may be used for the multiple beams. In another example, multiple base stations (e.g., 130 and 150) may be used with portable device 100 to improve the probabilities that a suitable line of sight communication channel exists, with the station offering the better conditions selected.

To find the correct beam steering angle and the correct beam forming, a scanning and optimization process may be performed in order to find the amplitude and phase of each antenna 202. This process may be referred to as beam shaping when phase is adjusted and beam forming when amplitude is adjusted. Given the processing delays associated with determining the appropriate phase and/or amplitude adjustments, it may be difficult to determine the appropriate parameters while delivering content at the desired rate. These difficulties are exacerbated when the user is moving, resulting in different channel conditions that may involve adaptations in the beam steering and forming. Correspondingly, by using data from motion sensors in portable device 100, the calculation associated with beam forming or beam steering may be simplified, thereby reducing latency of the system and reducing power consumption required for communication. In some embodiments, an initial beam optimization may be performed, without using motion sensor data, by employing a conventional channel optimization associated with the protocol being used, so that an optimized communication channel is in place between portable device 100 and base station 130. The initial weights w_{i,0} are the weights as determined by the initial beam optimization, and may be expressed, for example, as Equation (5):

w_{i,0}=a_{i,0}e^{jφ}^{_{i,0}} (5)

During the initial beam optimization, the position X of portable device 100 may be measured using data from sensors 112, 114 and/or 116. In reference to the position of portable device 100, it may be desirable to include the orientation, so that the position may be expressed as a 6D vector including 3 position coordinates (e.g. x, y, z) and 3 orientation coordinates (e.g. pitch, yaw, roll). Unless the context indicates otherwise, a position determination may include determining orientation. In some embodiments, only the orientation of portable device 100 may be used. The initial position of portable device 100 corresponding to the initial beam optimization process may be defined as X₀. The subsequent position X may then be determined using one or more motion sensors, the motion sensors being of the same or different type. For example, accelerometers, gyroscopes, and/or magnetometers may be used, but the signals from the different sensors may also be combined in a fusion process (as is known to the person skilled in the art). In addition, a pressure sensor with a high sensitivity may be used together with the motion sensors to help determine any elevation change. Other localization techniques, using e.g. reference-based techniques such as the global positioning system (GPS), global navigation satellite system (GLONASS), Galileo and Beidou, as well as WiFi™ positioning, cellular tower positioning, Bluetooth™ positioning beacons, or other similar methods.

The motion and position change of portable device 100 after the initialization is tracked using the motion sensors and is used to determine the position Xₜ at time t. The difference in position since the initialization may be expressed as dXₜ, and it is this difference that may be used to adapt the beam or otherwise adjust transmission or reception parameters. The position difference dXₜ may be used to directly adapt the weights wᵢ, for example by applying a correction to the amplitude and phase as a function of the difference. For example, the amplitude a_{i,t} and the phase φ_{i,t} may be modified using amplitude correction da_{i,t} and the phase correction dφ_{i,t}, according to Equations (6) and Equation (7) respectively:

a_{i,t}=a_{i,0}*da_{i,t} (6)

φ_{i,t}=φ_{i,0}+dφ_{i,t} (7)

The amplitude correction da_{i,t} and the phase correction dφ_{i,t} may be determined based on the measured change in position and/or orientation. In one aspect, a change in orientation angle of portable device 100 may be directly used as a measure for the phase correction dφ_{i,t}. For example, when the orientation angle changes by a certain amount of degrees, the phase may be modified by an equivalent or proportional amount. The orientation may change in multiple angles, such as e.g. the pitch angle, the yaw angle, and the roll angle, and therefore for a 2D antenna array the phase correction may also be multi-dimensional. The orientation (change) of portable device 100 may be expressed using quaternions, and a similarly the beam direction may also be expressed using quaternions. The beam optimization may then be computed using quaternion math. In some embodiments, it may be desirable to employ predictive quaternions or the equivalent to estimate a future position of portable device 100 so that adjustments to the communication parameters may be made preemptively by base station 130 rather than reactively. The correction of the phase and amplitude may be calculated based on the change in position/orientation using the change in geometric relations between the device and the basestation(s), and may include the knowledge of the geometric model of the antenna arrays. As such, a transform function may be determined that transforms a change in position/orientation into a change in phase and or amplitude for the antennas in the antenna array. The transform function may be a global transform function for the entire array, or may be a transform function related to groups or individual antennas in the antenna array. For example, a transform function of a single antenna may define the phase change and/or amplitude change of that antenna as a function of an angle change of the device as based on the sensor measurements. The transform functions may be predefined, or may be based on machine learning. In machine learning, in an initial step the antenna arrays may be optimized using conventional optimizing techniques without using the motion sensors as input. During this initial step, the change in phase and/or amplitude as defined through the optimization process is recorded and synchronized with the sensor measurements. In a subsequent step, the relation between the change in phase and/or amplitude and the measured change in position/orientation is analyzed, and at least one transform function is determined. Once the transform functions have been determined, they may be applied, meaning that the antenna arrays are then controlled through the motion sensor data, and no longer by conventional beam optimization methods. In some embodiments, a confidence factor may be attributed to the transform function, indicating the confidence in obtaining the correct antenna configuration determined based on the motion sensor data. The transform function may only be applied once the confidence factors are above a certain threshold. This may also mean that for some positions and/or orientations or position changes and/or orientation changes, the transform function may be applied, while for others, conventional techniques may be used. A feedback loop where the quality of the communication is used to verify the quality of the transform functions may also be used, for example, by monitoring the signal to noise ration of the communication. When the quality become lower than a preset thresholds, the system may revert back to conventional beam optimization techniques.

The position change as detected by the motion sensors may also be used to adapt/correct the amplitude distribution and/or phase distribution of the individual antennas 202 over the antenna array 128 or 138. The shape, amplitude, and location of these distributions may be directly adapted using the motion info. For example, the maximum of the phase distribution may be increased or decreased by the angle change as determined from the motion data. In some embodiments, a confidence of the determined position may be estimated and used to adjust communication parameters accordingly. For example, if the position is known with a higher confidence/accuracy, the relative shape of the resulting beam may be more narrow, but the beam dimensions may be increased as the uncertainty in the position increases. Correspondingly, dependent on any uncertainty in the position of portable device 100, the beam may be shaped/formed over a broader area to increase the probability of communication. This correction may be performed using the amplitude and/or phase distribution discussed above. Furthermore, if there is an uncertainty in the determined position of portable device 100, the beam may be shaped larger to accommodate the ambiguity, such as by covering the range of possible positions in order to improve the probability of a line of sight relationship between the antenna systems. Such uncertainty may be associated with a single technique for determining position, such as a sensor-only based determination, or may be associated with different techniques being used to determine position. For example, as discussed below, the characteristics of the wireless communication protocol may allow for determination of portable device 100 independently of the motion sensor data. Other positioning techniques may be employed as desired, including the referenced-based systems discussed above. Alternatively or in addition, ambiguities in position may be resolved by steering and/or forming the beam to different positions among the possibilities so that measurement of wireless characteristics, such as the SNR, may be used to select a more accurate position. The SNR, or other characteristics may also be used in a feedback look to verify and control the influence of the motion data on the beam forming/shape.

The geometry of portable device 100 and the placement of antennas comprising antenna system 128 may also influence the weights given to each antenna. For example, when the position of portable device 100 with respect to base station 130 is known, it may be determined which antennas are not in a line of sight condition and weight these antennas to zero to reduce power consumption, depending on geometry indicated by motion module 122. For this purpose, either base station 130 and/or portable device 100 may store a geometric model of relative position of the respective antenna arrays. When using the data from the motion sensors of portable device 100 to adjust communication parameters, the different reference frames should be considered. The inertial frame of reference, the Earth's frame of reference, or the base station reference frame is considered to be static, and in general base station 130, which typically is not moving, is defined in the inertial reference frame. The motion sensors may be mounted in portable device 100, having its own reference frame. In general, the axes of the motion sensors are aligned with the axes of the HMD, and if this is not the case, a standard (matrix) rotation correction may be performed. The antenna array 128 may have its own reference frame, particularly if implemented by or across another device. When this reference frame is not identical to the frame of portable device 100, a conversion matrix may be defined to convert the motion data from the reference frame of portable device 1000 to the antenna reference frame. This conversion matrix may be considered constant or intrinsic, when the antenna does not move with respect to portable device 100. In some embodiments, a calculation of the direction portable device 100 is facing may be corrected for the roll angle of portable device to obtain data in the correct reference frame. This principle is identical to ‘roll-compensation,’ which may be applied to remote controls used as pointing devices and details of suitable roll compensation techniques may be found in commonly owned U.S. Pat. No. 8,010,313, issued Aug. 30, 2011, which is hereby incorporated by reference in its entirety.

It will be appreciated that the larger the position or orientation change with respect to the initial position, the lesser the chance that any direct correction of the weights using the motion sensors will be optimal. Therefore, the determination of communication parameters may be performed at different stages. For example, a threshold may be set for the position/orientation change. One exemplary threshold may be of the order of a several degrees, e.g. 1-10 degrees. This process may be simpler than the initial optimization process since the beam forming or other determination of communication parameters has already been gradually adapted during the motion controlled beam optimization. A second larger threshold may be set to start a complete optimization process, so that exceeding the second threshold results in an active determination of communication parameters, such as through sending a training sequence, rather than a calculated derivation of the communication parameters based on the motion. Alternatively, the Signal to Noise Ratio (SNR), may also be determined during the motion controlled beam optimization, and when the SNR difference with respect to the initially obtained SNR becomes smaller than a predefined threshold, an active determination of communication parameters may be performed. In yet another example, a minimal threshold may be defined corresponding to motion in which no adjustment to communications parameters is made.

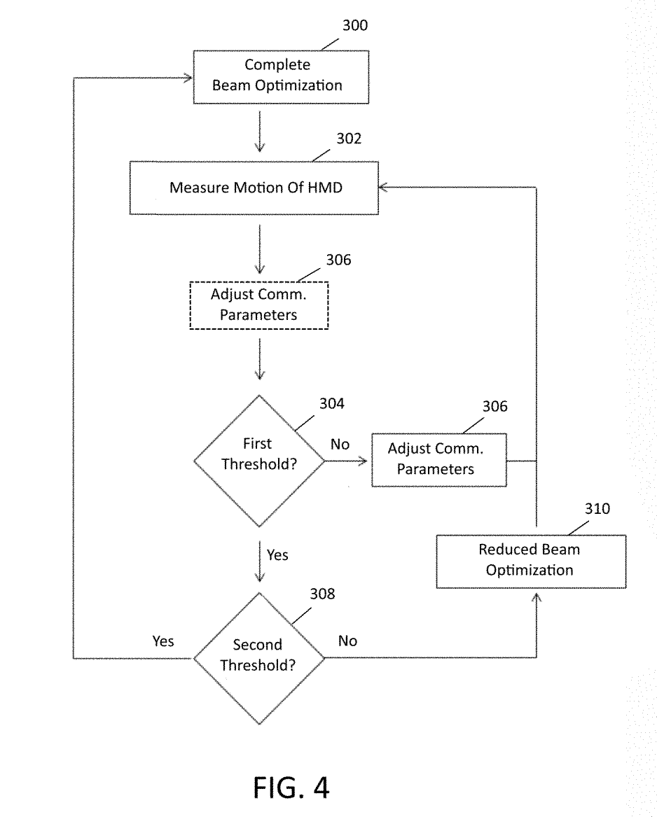

One exemplary implementation of the techniques of this disclosure is depicted in the flow diagram of FIG. 4. Beginning with 300, initial communications parameters may be determined conventionally for portable device 100, such as a HMD, and base station 130 as appropriate for the protocol being employed, such as by exchanging training sequences to estimate the channel and set the beam forming weights or beam steering phases. In the embodiments discussed below, a beam optimization operation may include an exchange of training information between communication nodes. Determining the initial communication parameters may be considered a complete beam optimization operation that is not dependent on the measured motion of portable device 100. In 302, motion module 122 may characterize any motion of portable device 100 with respect to base station 130 by processing sensor data, such as received from internal sensor 112, external sensor 114 and/or auxiliary sensor 116. Further, data may be received from user controller 152 with separate integrated motion sensors if available. As described above, the relative motion may correspond to changes in position, orientation and/or distance. In 304, the measured motion relative e.g. to the last time the beam optimization was performed may be compared to a first threshold, with the routine branching to 306 if the first threshold is not exceeded. Correspondingly, one or more parameters may then be adjusted in 306 based on the measured motion alone, such as through use of a transform function as described above or in any other suitable manner, and the routine may return to 302 to track further motion of portable device 100. Alternatively, when the first threshold is exceeded, the routine flows to 308 for comparison of the measured motion against a second threshold. When the second threshold is not exceeded, the routine may progress to 310 to perform a reduced beam optimization operation that is based on the measured motion, but requires some exchange of information between portable device 100 and base station 130. As will be appreciated, the reduced beam optimization operation may be simplified with respect to a complete beam optimization operation since at least some aspects of the relative positions of portable device 100 and base station 130 are known. Following the reduced beam optimization of 310, the routine again returns to 302 for further motion tracking. When the second threshold is exceeded as determined in 308, the routine branches instead to 300 to repeat the complete beam optimization.

Various modifications may be made to the routine of FIG. 4 as desired. As one example, adjustments to the communications parameters may be made directly following motion measurement in 302, as indicated by the optional positioning of 306 in the flow of the routine indicated by the dashed box. Accordingly, the routine would return directly to 302 upon determination that the measured motion did not exceed the first threshold in 304, given that the communication parameters have already been adjusted. This implementation may result in a quicker response to motion of portable device 100. In other embodiments, different amounts of relative motion may be accommodated through the use of more or fewer thresholds. For example, a single threshold may be used so that the communications parameters are adjusted based on the measured motion alone when the threshold is not exceeded and some degree of beam optimization relying on exchange of information between portable device 100 and base station 130 occurs when the threshold is exceeded. Further, any or all the thresholds may be based on SNR levels, so that the decisions of whether to adjust the communications parameters or to perform beam optimization are made when the SNR has decreased with respect to the threshold. Alternatively, the motion thresholds and SNR thresholds may be combined, such as by requiring one or both of the motion and SNR thresholds to be satisfied.

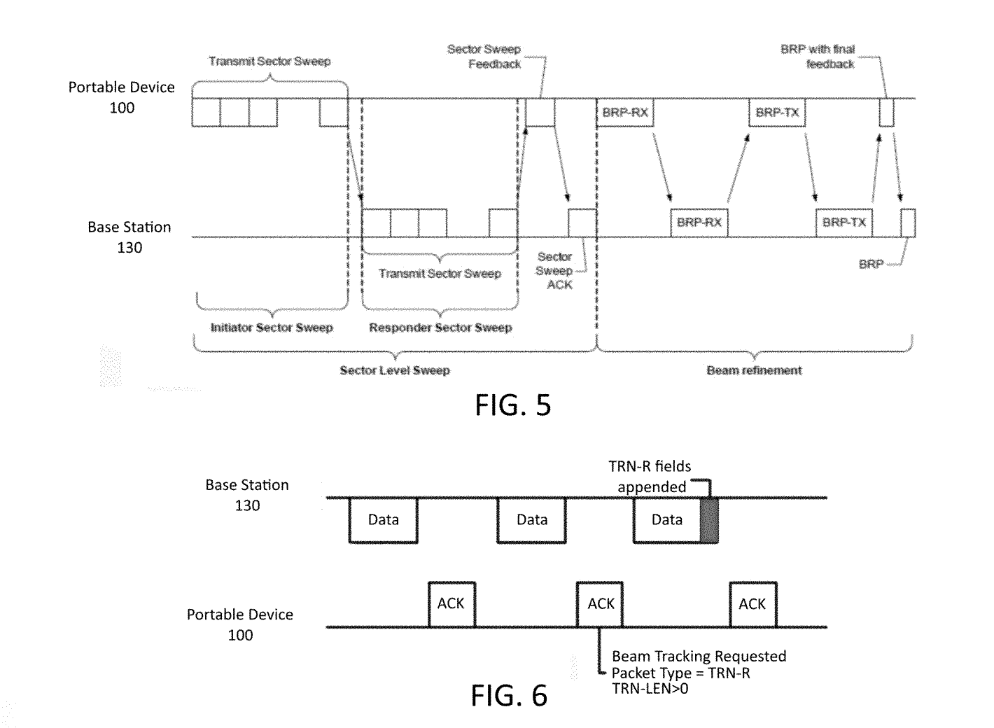

As will be appreciated, reduced and complete beam optimization operations may depend on the wireless protocol being employed. For example, the 802.11ad protocol includes optimizations related to a sector level sweep (SLS) and a beam refinement protocol (BRP) to set communications parameters associated with beam steering. Beam tracking may be employed to provide beam forming with channel estimates. In some embodiments, it may be desirable to employ a beam steering technique involving only phase adjustments to accommodate relatively small changes in position of portable device 100, while beam forming techniques that may involve phase and amplitude adjustments may be reserved for relatively larger changes in position. Moreover, some techniques may avoid the use of a training sequence by sequentially transmitting beams at various settings and selecting the communication parameters associated based on performance. An example of the information exchange between portable device 100 and base station 130 associated with a complete beam optimization operation is schematically depicted in FIG. 5. Correspondingly, an example of the information exchange between portable device 100 and base station 130 associated with a reduced beam optimization operation is schematically depicted in FIG. 6.

In addition to aiding communication between portable device 100 and base station 130, information determined by motion module 122 may be used for other purposes according to the techniques of this disclosure. For example, characteristics of the wireless communication protocol may be leveraged when calibrating one or more sensors of portable device 100. Notably, the 802.11ad protocol is highly directional and therefore is very sensitive to relative position changes. As such, when the communication signal is stable, it may be assumed that the position between portable device 100 and base station 130 is relatively unchanged. Since motion sensors, such as e.g. gyroscopes or accelerometers, may suffer from drift or bias problems, they may require periodic calibration. Accordingly, sensor measurements made when communication is stable may be attributed to sensor drift or bias offsets rather than motion of portable device 100. Other communication protocols may have similar characteristics or may have different characteristics that may be exploited.

As a representative example, the stability of wireless communication may be used as a trigger to initiate calibration. Changes in the communication signal, such as e.g. a change in SNR, may be determined over time. When the change is below an appropriate threshold, the position of portable device 100 may be assumed to be unchanged. To illustrate, consider that the signal conditions indicate that position of portable device 100 is unchanged between time t₁ and time t₂. Correspondingly, any measured motion by the motion sensors from time t₁ and time t₂ is most likely induced by drift and bias errors. The drift and bias may then be corrected so that the recalibrated motion sensors signals indicate a stable position of portable device in this time period.

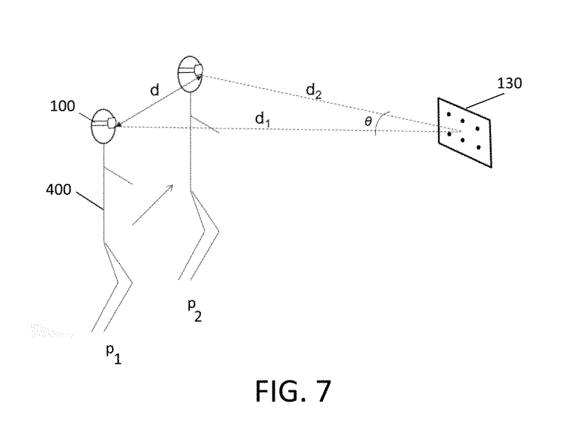

Another use for information determined by motion module 122 in conjunction with characteristics of the wireless communication may relate to determining or verifying user position. Although the position of portable device 100, and correspondingly the user of the device, may be determined using motion sensor information alone, such as through suitable dead reckoning techniques or sensor fusion operations involving any available motion sensor data (including any that may be obtained from auxiliary device such as user controller 152), position may also be determined based on the wireless communication. For example, time of flight (TOF) measurements of the communication signal may be used to determine the distance between portable device 100 and base station 130. The beam angle change θ at base station 130 corresponding due to a change in position of portable device 100 may also be determined. By using a geometric combination of the change in TOF and the change of beam angle, position of portable device 100 may be determined from characteristics of the wireless communication alone. An illustration of this concept is schematically depicted in FIG. 7. As shown, user 400 may be wearing portable device 100 (e.g., a HMD) and may change position from p₁ to p₂ as indicated by d. TOF measurements may be used to calculate the distance d₁ to base station 130 when the user is at p₁ as well the distance d₂ when the user is at p₂. The change in beam angle is indicated by θ, allowing for trigonometric determination of the change in user position. When employing a 802.11ad protocol, for example, the position determination may be relatively accurate, such as within approximately 1 cm in distance, 1° in yaw and 2.5° in pitch. Thus, the position change as determined from the wireless communication and the sensor-based position change may then compared and/or combined to obtain a position with improved accuracy. Confidence factors may be determined for both positions, and these factors may influence how the different position calculations are combined, with more confidence given more weight.

From the above, examples of communication parameters that may be adjusted include those associated with the beam forming or beam steering operations, including phase and/or amplitude of the signal at each antenna element. However, another communication parameter that may be adjusted is the timing of calibration. Further, the communication parameters may involve the content being delivered by base station 130. For example, a video stream may be composed of different types of frames such as intra-coded (I) frames that carry the most information and do not require other frames for decoding, predicted (P) frames that rely on previous frames for decoding and bidirectional predicted (B) frames that rely on previous and next frames for decoding. Since greater bandwidth may be required for I frames as compared to P or B frames, the timing of any beam optimization or other adjustment of communications parameters may be scheduled to avoid or reduce interference with the transmission of these frames depending on the detected amount of motion, orientation, or position. For example, during fast motion, the communication of the I-frames may be challenging and prone to error. Therefore, the I-frame transmission may be delayed until after the fast motion. This means that maybe a slight decrease in image quality occurs, but this is likely not perceivable because of the high motion. In embodiments where fast motion phases may be predicted, content may be transmitted in advance and buffered on the HMD in anticipation of the more difficult communication during the upcoming fast motion period. For example, fast motion phases may be predicted in certain gaming applications. Yet another communication parameter that may be adjusted is the selection of which antennas of an array are activated or deactivated. This may involve more than setting the gain to zero for a particular antenna element, given that there may be additional power consumption even at zero gain. For example, improved power savings may be achieved by shutting down the radio frequency (RF) chain associated with an antenna.

In some embodiments, device 100 may receive image data from one or more base stations, but may additionally also be able to provide or generate image data itself through available processing resources. As such, the system may be used as a standalone device when needed, and depend on the base station when available. For example, when communication with the base station is impossible or difficult due to a certain position, orientation, or motion, the system may switch to stand alone mode, and may switch back to communication with the base station when possible. Thus, selection among available modes of operation of device 100 may depend on the motion sensor information.

From the above materials, it will be appreciated that this disclosure includes a method for providing wireless communication between a portable device and a first base station utilizing information about the relative motion of the portable device.

In one aspect, adjusting the communication parameters may be performed at the portable device.

In one aspect, adjusting the communication parameters may be performed at the first base station.

In one aspect, adjusting the communication parameters may involve adjusting an antenna array of the portable device. Adjusting the antenna array may involve phase shifting at least one antenna of the antenna array with respect to at least one other antenna of the antenna array. Adjusting the antenna array may involve altering a gain associated with at least one antenna of the antenna array with respect to at least one other antenna of the antenna array. Further, altering the gain associated with at least one antenna of the antenna array may be based at least in part estimating a channel between the portable device and the first base station using the motion sensor data.

In one aspect, the method may involve determining which antennas in an antenna array of the portable device and an antenna array of the first base station have a line of sight relationship using the motion sensor data. Adjusting the communication parameters may involve activating antennas determined to have the line of sight relationship.

In one aspect, at least a second base station may be provided, so that it may be determined which antennas in the antenna array of the portable device and an antenna array of the second base station have a line of sight relationship using the motion sensor data, and thereby selecting between the first base station and the second base station when implementing the wireless communications link based at least in part on the determined line of sight relationship between antennas in the antenna array of the portable device and antennas in the antenna arrays of the first base station and the second base station.

In one aspect, adjusting the communication parameters may also based at least in part on a transform function. The transform function may be derived using a machine learning technique applied to previously determined communication parameters and the associated motion sensor data.

In one aspect, the motion sensor data comprises a fusion of data from different types of motion sensors.

In one aspect, adjusting the communication parameters based at least in part on the motion sensor data may involve a beam optimization operation between the portable device and the first base station. The beam optimization may involve an exchange of training information between the portable device and the first base station this is initiated when the motion sensor data indicates displacement of portable device from a previous location exceeds a threshold. Further, an exchange of training information between the portable device and the first base station may be initiated when signal quality of the wireless communications link degrades beyond a threshold. A subsequent adjustment of the communication parameters may be performed based at least in part on the motion sensor data without an exchange of training information between the portable device and the first base station.

In one aspect, the method may involve assessing confidence in a motion determination for the portable device, wherein adjusting the communication parameters is also based at least in part on the confidence assessment.

In one aspect, the method may involve correcting a roll angle for an orientation determined for the portable device from the motion sensor data.

In one aspect, the motion sensor data may be obtained from sensors integrated with the portable device. The motion sensor data may be obtained from at least from at least one auxiliary device associated with the portable device.

In one aspect, the method may involve assessing the wireless communication link and initiating a calibration of a sensor used to provide the motion sensor data for the portable device. The calibration may be initiated when the wireless communication link assessment indicates stability within a threshold.

In one aspect, a change in position of the portable device may be determined based at least in part on the wireless communications link. The change in position may be determined by time of flight calculations performed on the wireless communications link and an angle of arrival derived from the motion sensor data.

In one aspect, the method may further involve selecting among operating modes of the portable device based at least in part on the motion sensor data.

Although the present invention has been described in accordance with the embodiments shown, one of ordinary skill in the art will readily recognize that there may be variations to the embodiments and those variations would be within the spirit and scope of the present invention. For example, the techniques of this disclosure have been explained in the context of a moving HMD and a static base station. In such applications, a high data transfer rate may be required, favoring directional communications. Therefore, the techniques may also be applied to other applications and devices that require a directional communication and are portable and can change in position similar. As will be appreciated the invention may be applied to other portable devices, such as e.g. smartphone, tablets, video game consoles, and other types of AR/VR viewers. In some aspects, the invention may be applied to applications or systems where the source may also be moving or portable, in which case the same principles of measuring the position change and adapting the antenna weights accordingly may be applied.

What is claimed is:

1. A method for wireless communication between a portable device and a first base station, comprising:
establishing a wireless communications link between the portable device and the first base station;
obtaining sensor data indicative of motion of the portable device relative to the first base station; and
adjusting communication parameters based at least in part on the motion sensor data.

2. The method of claim 1, wherein adjusting the communication parameters comprises adjusting an antenna array of the portable device.

3. The method of claim 2, wherein adjusting the antenna array comprises phase shifting at least one antenna of the antenna array with respect to at least one other antenna of the antenna array.

4. The method of claim 2, wherein adjusting the antenna array comprises altering a gain associated with at least one antenna of the antenna array with respect to at least one other antenna of the antenna array.

5. The method of claim 4, wherein altering the gain associated with at least one antenna of the antenna array is based at least in part estimating a channel between the portable device and the first base station using the motion sensor data.

6. The method of claim 1, further comprising determining which antennas in an antenna array of the portable device and an antenna array of the first base station have a line of sight relationship using the motion sensor data so that adjusting the communication parameters comprises activating antennas determined to have the line of sight relationship.

7. The method of claim 6, further comprising:
providing a second base station;
determining which antennas in the antenna array of the portable device and an antenna array of the second base station have a line of sight relationship using the motion sensor data; and
selecting between the first base station and the second base station when implementing the wireless communications link based at least in part on the determined line of sight relationship between antennas in the antenna array of the portable device and antennas in the antenna arrays of the first base station and the second base station.

8. The method of claim 1, wherein adjusting the communication parameters based at least in part on the motion sensor data comprises a beam optimization operation between the portable device and the first base station.

9. The method of claim 8, further comprising initiating an exchange of training information between the portable device and the first base station when the motion sensor data indicates displacement of portable device from a previous location exceeds a threshold.

10. The method of claim 8, further comprising initiating an exchange of training information between the portable device and the first base station when signal quality of the wireless communications link degrades beyond a threshold.

11. The method of claim 8, wherein a subsequent adjustment of the communication parameters is performed based at least in part on the motion sensor data without an exchange of training information between the portable device and the first base station.

12. The method of claim 1, further comprising assessing confidence in a motion determination for the portable device, wherein adjusting the communication parameters is also based at least in part on the confidence assessment.

13. The method of claim 1, wherein adjusting the communication parameters is also based at least in part on a transform function.

14. The method of claim 13, wherein the transform function is derived using a machine learning technique applied previously determined communication parameters and the associated motion sensor data.

15. The method of claim 1, wherein the motion sensor data is further obtained from at least from at least one auxiliary device associated with the portable device.

16. The method of claim 1, further comprising assessing the wireless communication link and initiating a calibration of a sensor used to provide the motion sensor data for the portable device.

17. The method of claim 16, wherein the calibration is initiated when the wireless communication link assessment indicates stability within a threshold.

18. The method of claim 1, further comprising determining a change in position of the portable device based at least in part on the wireless communications link.

19. The method of claim 18, wherein the change in position is determined by time of flight calculations performed on the wireless communications link and an angle of arrival derived from the motion sensor data.

20. The method of claim 1, further comprising selecting among operating modes of the portable device based at least in part on the motion sensor data.

21. A portable device comprising:
a wireless communication module;
a sensor assembly providing data indicative of motion of the portable device;
a motion module configured to receive the sensor data to measure motion of the portable device;
wherein the wireless communication module employs communication parameters adjusted based at least in part on the measured motion when communicating with a first base station.

22. A base station comprising a wireless communication module configured to receive information corresponding to motion of a portable device and to employ communication parameters adjusted based at least in part on the motion information when communicating with the portable device.

23. A wireless communication system comprising:
a portable device having;
a wireless communication module;
a sensor assembly providing data indicative of motion of the portable device; and
a motion module configured to receive the sensor data to measure motion of the portable device; and
a base station comprising a wireless communication module;
wherein the wireless communication modules employ communication parameters adjusted based at least in part on the measured motion when communicating between the portable device and the base station.
